(19) United States
(12) Patent Application Publication
(10) Pub. No.: US 2011/0147892 A1
(43) Pub. Date: Jun. 23, 2011

(54) Bipolar Transistor with Pseudo Buried Layers

(76) Inventors: Tzuyin Chiu, Shanghai (CN); TungYuan Chu, Shanghai (CN); Wensheng Qian, Shanghai (CN); YungChieh Fan, Shanghai (CN)

(21) Appl. No.: 12/966,241

(22) Filed: Dec. 13, 2010

(30) Foreign Application Priority Data
Dec. 21, 2009 (CN) 200910202011.7

(51) Int. Cl. H01L 29/70; H01L 21/331

(52) U.S. Cl. 257/565; 438/353; 257/E21.37; 257/E29.171

(57) ABSTRACT

A structure and fabrication method for a bipolar transistor with shallow trench isolation (STI) comprises a collector formed by implanting first electric type impurity in active area; pseudo buried layers at the bottom of STI at both sides of active area by implanting heavy dose of first electric type impurity; deep contacts through field oxide to connect to pseudo buried layers and to pick up the collector; a base, a thin film deposited on the collector and doped with second electric type impurity; an emitter, a polysilicon film doped by heavy dose implant of first electric type impurity. This transistor has smaller device area, less parasitic effect, less photo layers and lower process cost.

The current application claims a foreign priority to an application in China with a serial number 200910202011.7 filed on Dec. 21, 2009.

### FIELD OF THE INVENTION

This invention relates generally to semiconductor devices in integrated circuits. More particularly it relates to bipolar transistor design and fabrication.

### BACKGROUND OF THE INVENTION

In radio frequency (RF) applications, higher and higher cut-off frequency (Fₜ) of RF transistor is required. RFCMOS with advanced technology nodes can realize high cut-off frequency. However RFCMOS still cannot satisfy RF requirement ((Fₜ higher than 40 GHz), and further more, advanced CMOS process is quite expensive. The compound semiconductor devices can achieve very high Fₜ, while their expensive materials, small size substrate and material poisonousness limit their applications. Silicon bipolar junction transistor (BJT) and SiGe hetrojunction bipolar transistor (HBT) are the best options of high Fₜ devices.

NPN transistor is taken as the example to describe conventional bipolar transistor structure. Conventional NPNs or HBTs all adopt N+ heavily doped collector buried layer (NBL) to reduce collector resistance. NBL is picked up by N+ sinker which is also N type heavily doped and linked to NBL. Local collector is in-situ N− doped epitaxial silicon layer on NBL. The base is formed by P type in-situ doped epitaxial growth, and a N type heavily in-situ doped polysilicon layer is grown as the emitter on the base. The different dose N type impurities is implanted through emitter window to additionally dope local collector for transistor breakdown voltage and Fₜ adjustment. The deep trench isolation is adopted to reduce parasitic capacitance of collector/substrate and then improve transistor's frequency characteristic. The conventional bipolar transistor's structure is shown as FIG. 1 including collector 114, base 111 and emitter 110. The collector 114 is N type area with middle concentration grown on NBL102, and is picked up by N+ sinker 104, N+ NBL102, contact 106 through inter layer dielectric 105 and collector electrode 104. N+ sinker 104 is doped by high dose, high energy N type implant. At both sides of the collector 114, there are STI or LOCOS isolations 103 and at the bottom of STI, there are deep trench isolations 115 filled with polysilicon to improve transistor isolation. The base 111 is P type doping epitaxial layer, and is picked up by the electrodes on external poly base 108 on field oxide 113. The emitter 110 is epitaxial polysilicon layer grown on base 111 and is heavily doped by N type impurity. The oxide spacer 112 is fabricated around the emitter 110. The emitter window opened in dielectric layer 109 determines the contacting area of base/emitter. In emitter window, the additional collector implant through base can modify breakdown voltage and Fₜ.

The fabrication of conventional bipolar transistors is a mature and reliable process. However it has some disadvantages: 1. too expensive for collector epitaxy; 2. Collector pick-up is formed by high dose, high energy implant. Its occupied area is large; 3. Deep trench isolation process is complicated and expensive; 4. There are too many photo mask layer to fabricate transistors.

### SUMMARY OF THE INVENTION

It is therefore an object of the present invention to offer a bipolar transistor with smaller device size, less parasitic effect, fewer photo mask layers and lower process cost.

The object of the invention is accomplished by providing a bipolar semiconductor device structure and related process including (a) a collector is formed by implanting first electric type impurity in active area with single or multiple implant steps; (b) pseudo buried layers at the bottom of STI at both sides of active area are formed by implanting heavy dose of first electric type impurity. The pseudo buried layers link in active area and form buried layer under local collector; (c) deep trench contacts through field oxide are used to connect to pseudo buried layers and to pick up the collector. The deep trenches are coated with barrier metal Ti/TiN first and then filled up with Tungsten. If the pseudo buried layer concentration satisfies with the requirement of ohmic contact, deep contacts touch pseudo buried layers directly. Otherwise The first type impurity of high dose is implanted into deep contacts after contact etch for better ohmic contact; (d) a thin film as the base is deposited on the collector and doped with second electric type impurity; (e) a polysilicon film as the emitter is deposited on the base and doped by heavy dose implant of first electric type impurity.

For NPN transistor, the first electric type is N type, and the second electric type is P type; For PNP transistor, the first electric type is P type, and the second electric type is N type.

If active critical dimension is less than 0.5 micron, the pseudo buried layers in STI areas at both sides of active area are overlapped by impurity lateral diffusion otherwise besides pseudo buried layer implants in STI areas, another implant of same type impurity as pseudo buried layer doping is performed in all area of the transistor to link two pseudo buried layers at two STI bottoms and to form buried layer under local collector.

The invention of bipolar transistor omits conventional collector buried layer process, collector epitaxial growth and heavily doped collector pick-up. Instead the pseudo buried layers implanted at the bottoms of shallow trenches are taken as buried layers, the collector area is formed by implantations, and the deep trench contacts in field oxide are used for collector pick-up. Compared to conventional bipolar transistors, the bipolar transistor in present invention has smaller device size, less parasitic effect, fewer photo mask layers and lower process cost.

### BRIEF DESCRIPTION OF THE DRAWINGS

The foregoing and the object, features, and advantages of the invention will be apparent from the following detailed description of the invention, as illustrated in the accompanying drawings, in which:

FIG. 1 is cross sectional view showing the structure of conventional bipolar transistors.

FIG. 2 is cross sectional view showing the structure of the bipolar transistors in the invention.

FIG. 3-10 are cross sectional views showing the structure at several steps in the process for making a bipolar transistor structure of the present invention.

FIG. 11A is TCAD simulated cross sectional view showing the structure of the bipolar transistors in the invention.

FIG. 11B shows TCAD simulated impurity lateral distribution profile of pseudo buried layer in a bipolar transistor of the present invention.

FIG. 12 shows TCAD simulated bipolar transistor characteristics of the present invention.

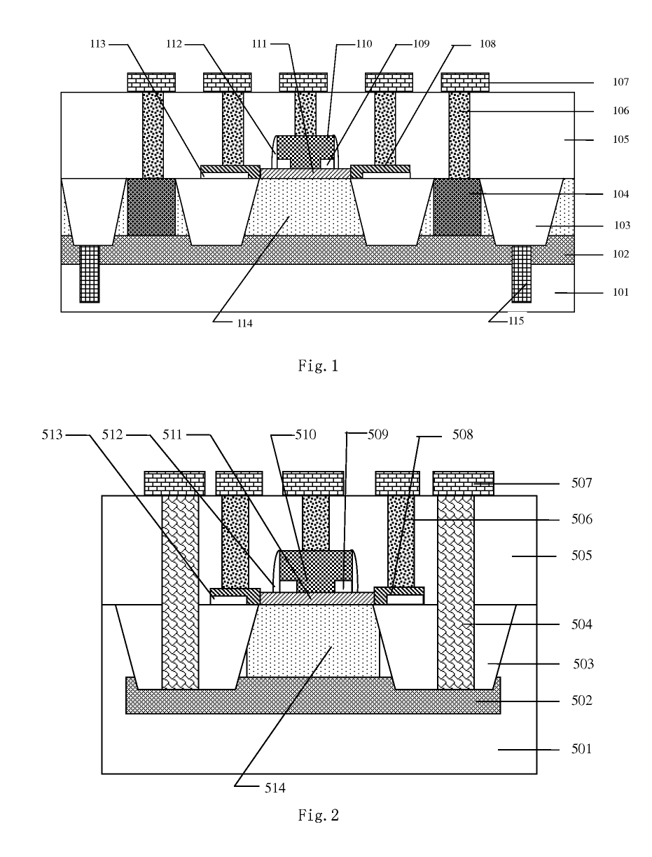

### DETAILED DESCRIPTION OF THE INVENTION

FIG. 2 is cross sectional view showing the structure of the bipolar transistors in the invention. On substrate 501, the active area is isolated by field oxide 503 in shallow trenches. The transistor comprises a collector 514, a base 511 and an emitter 510.

The collector 514 is formed by single or multiple implants of first electric type impurity into active area. At the bottom of collector 514, two pseudo buried layers 502 at STI bottoms link up to be buried layer. For active critical dimension less than 0.5 micron, two pseudo buried layers 502 overlap in active by lateral diffusion and become collector 514's buried layer. If active critical dimension is larger than 0.5 micron, the implant into active with the same impurity type as pseudo buried layer 502 is implemented to link two pseudo buried layers. The implant depth is almost same as that of pseudo buried layers. The deep trench contacts 504 are etched through the field oxide 503 above pseudo buried layers 502 to connect collector buried layer to metal 507. The deep trench contacts are coated with barrier metal Ti/TiN and then filled up with tungsten. If the pseudo buried layer concentration satisfies with the requirement of ohmic contact, deep contacts touch pseudo buried layers directly. Otherwise The first type impurity of high dose is implanted into deep contacts after contact etch for better ohmic contact.

The base 511 is a semiconductor thin film grown on the collector 514 and in-situ doped by second electric type impurity. The metal contact 506 touches poly base 508 on field oxide to pick up the base.

The emitter 510 is a poly silicon thin film grown on base 511 and doped with first electric type impurity by in-situ doping or implants. The metal contact picks up emitter 510 directly. The emitter window is defined by the emitter dielectric 509. Oxide spacers 512 are fabricated at both sides of emitter 510.

FIG. 2 to FIG. 10 illustrate the fabrication of the bipolar transistor in the present invention. The main process steps are:

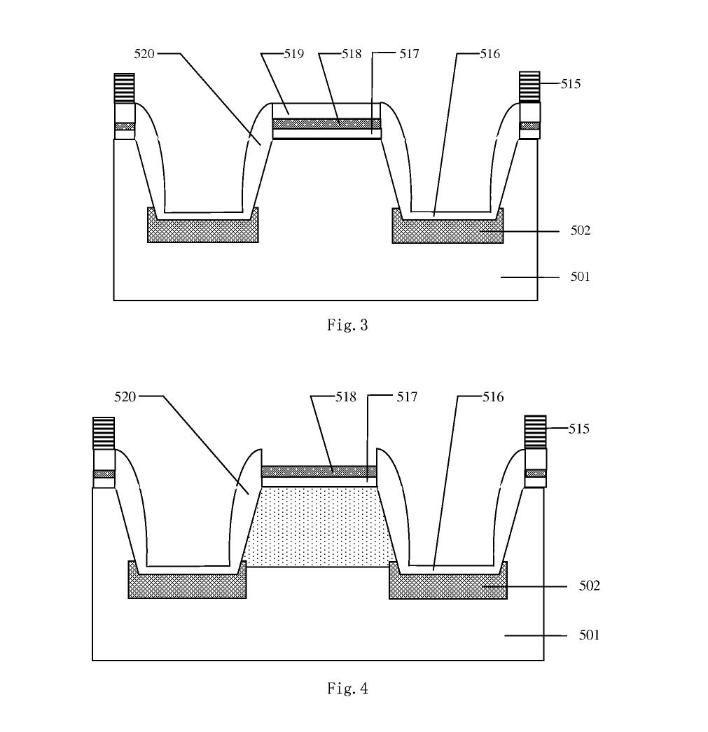

1. As illustrated in FIG. 3, The hard mask layers (oxide 519/nitride 518/oxide 517) are deposited on substrate. The total layer thickness is determined by the implant energy into pseudo buried layers to prevent the impurities from penetrating through the hard mask. Three layer thickness ranges are: first oxide film 517 thickness is from 100 Å to 300 Å, second nitride film 518 thickness is from 200 Å to 500 Å, third oxide film 519 thickness is from 300 Å to 800 Å.

2. As illustrated in FIG. 3, shallow trench area is selected by advantage of active photolithography and then is etched.

3. As illustrated in FIG. 3, HTO oxide 516 is deposited after liner oxidation. Inner spacers 520 are formed by dry etch.

4. As illustrated in FIG. 3, bipolar transistor area is opened by photolithography. The first type implant is done to form pseudo buried layers. The other areas except bipolar transistors are covered by photo resister 515. The implant dose range of pseudo buried layers is from 1e14 cm⁻² to 1e16 cm ⁻².

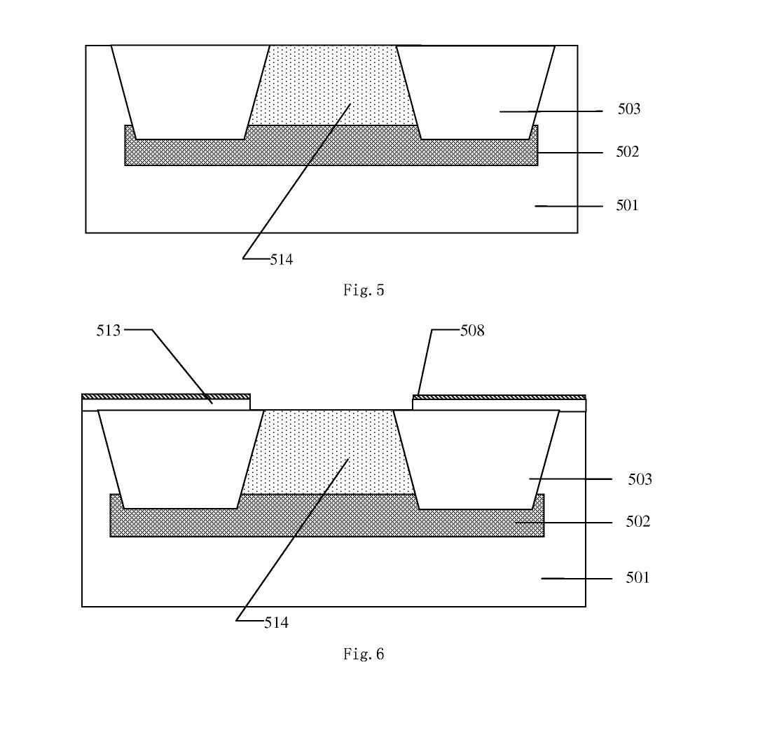

5. As illustrated in FIG. 4, The third layer oxide film 519 is removed by wet etch. The first type impurity is implanted through nitride film 518 and oxide film 517 to form collector 514. The implants are single one or multiple one with different doses and energies. The implant dose and energy depend on transistor's breakdown voltage.

6. As illustrated in FIG. 5, field oxide HDP 503 is filled in shallow trenches, CMP of HDP is done to planarization. Hard masks are removed. The pseudo buried layers 502 are link up by impurity lateral diffusion.

7. As illustrated in FIG. 5, CMOS related process steps are implemented such as gate oxide, gate formation, MOS transistor spacers, etc.

8. As illustrated in FIG. 6, the film stack of polysilicon 508/oxide 513 are deposited for base window formation. The thickness ranges of 513 and 508 are 100 Å˜500 Å, 200 Å˜1500 Å, respectively

9. As illustrated in FIG. 6, the base window is opened by photolithography and etch.

10. As illustrated in FIG. 7, the base film 511 with second electric type doping is grown. The film can be silicon, SiGe, SiGeC, etc.

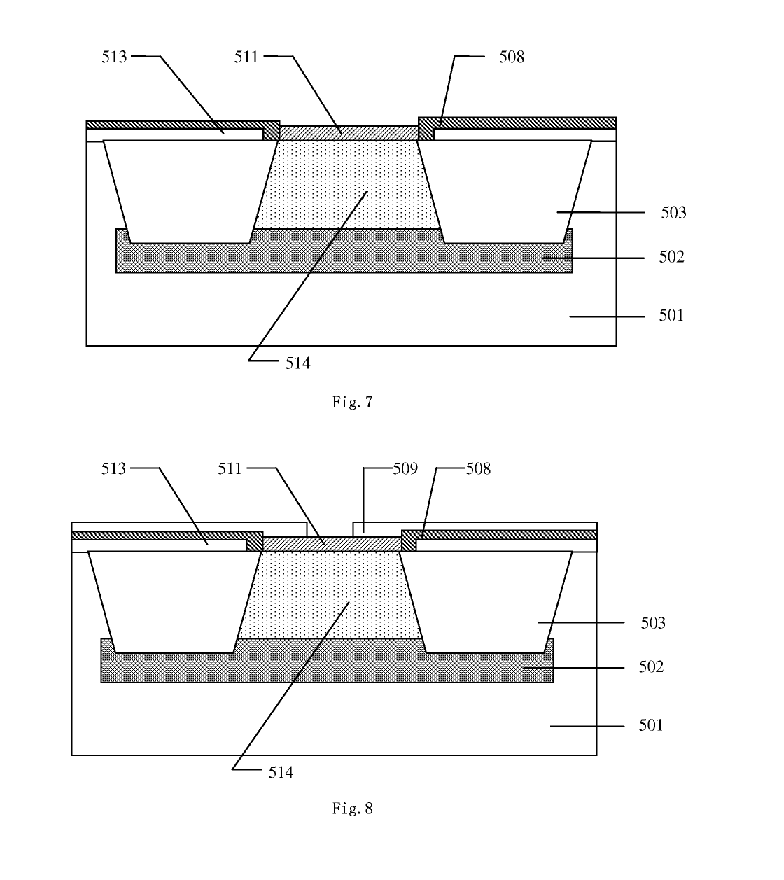

11. As illustrated in FIG. 8, the dielectric 509 is deposited for opening emitter window. The thickness is determined by emitter width. The dielectric 509 can be pure oxide film, nitride/oxide or polysilicon/oxide stacks.

12.As illustrated in FIG. 8, the emitter window is opened by photolithography and etch.

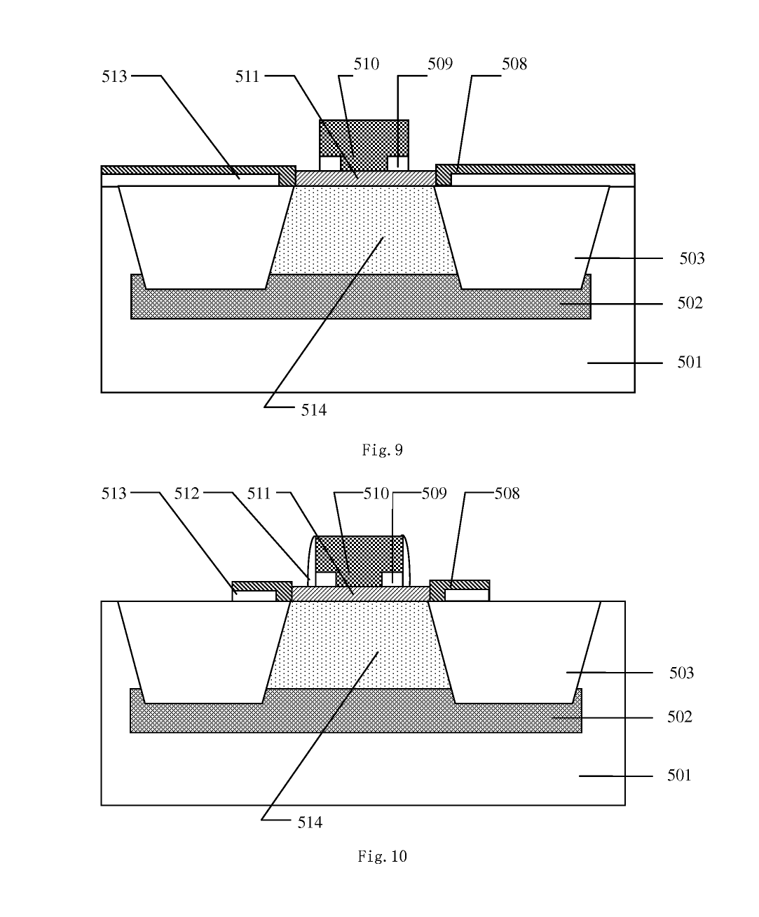

13. As illustrated in FIG. 9, the polysilicon emitter 510 is deposited with in-situ doping of first electric type impurity, and the first type impurity implant with dose higher than 1e15cm⁻² is done. The implant energy depends on the emitter thickness.

14. As illustrated in FIG. 10, the emitter 510 is formed by dry etch. Oxide film is deposited and oxide spacers 512 are formed by dry etch.

15. As illustrated in FIG. 10, the base dielectric stack 508/513 is etched.

16. As illustrated in FIG. 2, The internal layer dielectric 505 (BPSG or PSG) between metal and silicon is deposited.

17. As illustrated in FIG. 2, The holes of deep trench contact 504 are formed by etch in shallow trenches.

18. As illustrated in FIG. 2, the holes of base and emitter contacts 506 are formed by etch.

19. As illustrated in FIG. 2, the barrier metal stack TiN/Ti is deposited to coat deep contact holes, tungsten fills up deep contact holes. CMP process makes planarization of the wafers.

20. As illustrated in FIG. 2, the first layer metal 507 is deposited and is etched after photolithography.

21. Conventional backend process steps are followed.

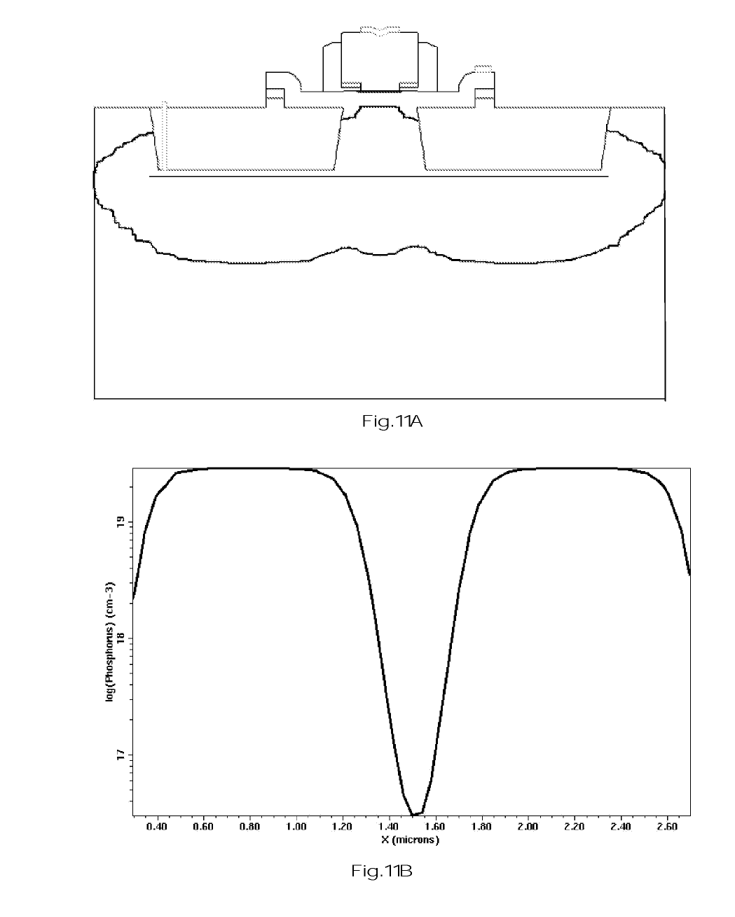

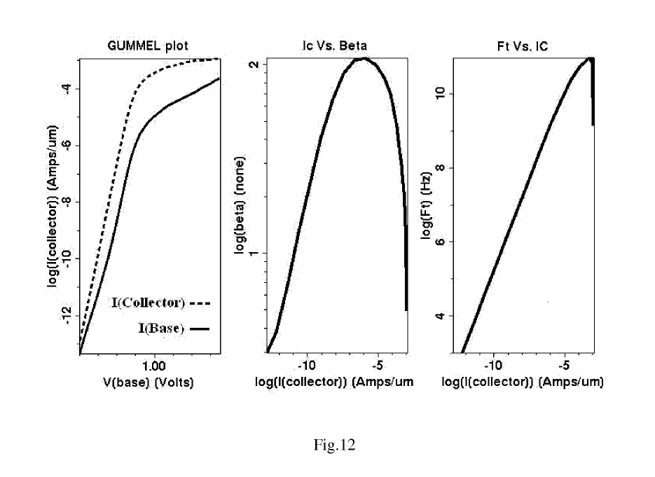

FIG. 11A and FIG. 11B are TCAD simulated bipolar transistor structure of the invention and lateral impurity profile of pseudo buried layers, respectively. The pseudo buried layers are formed by low energy implant in shallow trenches, and link up in active to form buried layer of the collector by impurity lateral diffusion during thermal process. Few impurities in the pseudo layers diffuse into local collector and have no impact on base/collector junction breakdown. The impurity concentration of pseudo buried layers is high due to high dose, low energy implant, and the junction area of pseudo buried layer/substrate is small, thus the parasitic capacitance C_{cs} is low, and also good ohmic contacts can be formed between bather metal TiN/Ti and pseudo buried layers to ensure low parasitic resistance of the collector.

As illustrated in FIG. 12, high current gain factor and high cut-off frequency are achieved in bipolar transistor characteristic simulation by TCAD. The performance is comparable with conventional transistors and verifies the process feasibility of the present invention. High cut-off frequency demonstrates the bipolar transistor of the invention still has low parasitic capacitance and resistance as well as good RF characteristics by lack of collector buried layer, collector epitaxial layer and deep trench isolations.

It will be apparent to those skilled in the art that various modifications and variations can be made in the fabrication method for a bipolar transistor of the invention without departing from the spirit or scope of the invention. Thus, it is intended that the present invention cover the modifications and variations of this invention provided they come within the scope of the appended claims and their equivalents.

1. A structure for a bipolar transistor with shallow trench isolation (STI) comprises,
a collector being formed by implanting first electric type impurity in an active area;
pseudo buried layers being disposed at the bottom of the STI at two sides of the active area;
deep contacts through field oxide for collector pick-up;
a base being deposited on the collector and being doped with second electric type impurity;
an emitter being doped by heavy dose implant of first electric type impurity.

2. A structure of a bipolar transistor as claimed in claim 1, wherein the electric types of doping impurities are:
for a NPN transistor, the first electric type is N type, and the second electric type is P type; For PNP transistor, the first electric type is P type, and the second electric type is N type;

3. The fabrication method of bipolar transistors with pseudo buried layers, wherein the pseudo buried layers are formed by implanting first electric type impurity in STI areas at both sides of active area and overlapping with impurity lateral diffusion when active critical dimension is less than 0.5 micron, otherwise besides pseudo buried layer implants in STI areas, another first electric type implant is performed in all area of the transistor to link two pseudo buried layers at two STI bottoms.

4. The fabrication method of claim 3, wherein first electric type impurity implants into collector area can be single implant or multiple implants.

5. The fabrication method of claim 3, wherein the deep contact is filled by Ti/TiN buried metal and tungsten.

6. The fabrication method of claim 3, wherein deep contact implant of first electric type impurity is performed after deep contact etch to form ohm contact.
